(19) United States
(12) Patent Application Publication
(10) Pub. No.: US 2021/0328180 A1
(43) Pub. Date: Oct. 21, 2021

(54) ENCAPSULATION THIN FILM, METHOD OF MANUFACTURING ENCAPSULATION THIN FILM, ORGANIC LIGHT-EMITTING DISPLAY PANEL, AND METHOD OF MANUFACTURING ORGANIC LIGHT-EMITTING DISPLAY PANEL

(71) Applicant: WUHAN CHINA STAR OPTOELECTRONICS SEMICONDUCTOR DISPLAY TECHNOLOGY CO., LTD, Wuhan, Hubei (CN)

(72) Inventor: Zhenyu ZHAO, Wuhan, Hubei (CN)

(73) Assignee: WUHAN CHINA STAR OPTOELECTRONICS SEMICONDUCTOR DISPLAY TECHNOLOGY CO., LTD, Wuhan, Hubei (CN)

(21) Appl. No.: 16/616,085

(22) PCT Filed: Aug. 8, 2019
(86) PCT No.: PCT/CN2019/099712

§ 371 Date: Nov. 22, 2019

(30) Foreign Application Priority Data
Jul. 19, 2019 (CN) 201910653955.X

(51) Int. Cl. H01L 51/52; H01L 51/56

(52) U.S. Cl. CPC H01L 51/5253; H01L 51/56; H01L 51/5259

(57) ABSTRACT

The disclosure provides an encapsulation thin film, a method of manufacturing the encapsulation thin film, an organic light-emitting display panel, and a method of manufacturing the organic light-emitting display panel. Moisture absorbing material is added to an organic layer. Moisture and oxygen, which invade during a process of manufacturing the encapsulation thin film or from defects of the encapsulation thin film, can be absorbed by the moisture absorbing material, which can prevent moisture and oxygen from keeping invading an organic light-emitting device. The organic light-emitting device's moisture blocking ability can be improved, thereby ensuring that the organic light-emitting device can be used normally.

### FIELD

The present disclosure relates to fields of thin film encapsulation and display technology and, more particularly, relates to an encapsulation thin film, a method of manufacturing the encapsulation thin film, organic light-emitting display panel, and a method of manufacturing the organic light-emitting display panel.

### BACKGROUND

Organic light-emitting diodes (OLEDs) are exceptional in terms of cost, viewing angles, contrast, and flexibility, which pan out in both small-size and large-size applications. The OLEDs are continuously encroaching market share of liquid crystal displays (LCDs).

Moisture will seriously affect lifetime of an organic light-emitting device which is a vital component of organic light-emitting display panels. First, moisture is prone to react with a conductive material of a cathode of an organic light-emitting device. Secondly, moisture is prone to chemically react with a hole transport layer, an electron transport layer, and a luminescent layer of the organic light-emitting device, leading to failure of the organic light-emitting device. To solve the above problem, thin film encapsulation (TFE) is usually used to encapsulate the organic light-emitting device in the organic light-emitting display panels of conventional technology. An encapsulation thin film of the TFE includes non-organic layers and organic layers which are alternately stacked and are configured to prevent moisture and oxygen from invading the organic light-emitting device.

A conventional encapsulation thin film can only passively block moisture and oxygen. However, moisture and oxygen, which invade during process of manufacturing the encapsulation thin film or invade from defects of the encapsulation thin film, cannot be blocked by conventional encapsulation thin films, thereby threatening lifetime of the organic light-emitting device.

Regarding the technical problem, the conventional encapsulation thin film cannot block moisture and oxygen which invade during process of manufacturing the encapsulation thin film or invade from defects of encapsulation thin film.

### SUMMARY

The present disclosure provides an encapsulation thin film. The encapsulation thin film includes at least one non-organic layer and at least one organic layer which are alternately stacked. The at least one organic layer includes an organic matrix and moisture absorbing material distributed in the organic matrix.

The present disclosure further provides an organic light-emitting display panel. The organic light-emitting display panel includes an organic light-emitting device and the above encapsulation thin film. One of the at least one non-organic layer of the encapsulation thin film covers a surface of the organic light-emitting device.

The present disclosure further provides a method of manufacturing an encapsulation thin film, including the following steps: forming a non-organic layer; and forming an organic layer on the non-organic layer or forming at least one organic layer and at least one non-organic layer which are alternately stacked on the non-organic layer. The organic layer includes an organic matrix and moisture absorbing material distributed in the organic matrix.

Regarding the beneficial effects: in the present disclosure, the moisture absorbing material is added to the organic layer. Moisture and oxygen, which invade during process of manufacturing the encapsulation thin film or invade from defects of the encapsulation thin film, can be absorbed by the moisture absorbing material, which can prevent moisture and oxygen from keeping invading the organic light-emitting device. The organic light-emitting device's moisture blocking ability can be improved, thereby ensuring that the organic light-emitting device can be used normally.

### DESCRIPTION OF DRAWINGS

FIG. 1 is a schematic structural view of an encapsulation thin film according to an embodiment of the present disclosure.

FIG. 2 is a schematic structural view of an organic light-emitting display panel according to an embodiment of the present disclosure.

FIG. 3 is a schematic flowchart showing a method of manufacturing an encapsulation thin film according to an embodiment of the present disclosure

FIG. 4 is a schematic flowchart showing a method of manufacturing an organic layer according to an embodiment of the present disclosure.

FIG. 5 is a schematic flowchart showing a method of manufacturing an organic light-emitting display panel according to an embodiment of the present disclosure.

FIG. 6 is a schematic flowchart showing a method of manufacturing an organic layer of an organic light-emitting display panel according to an embodiment of the present embodiment.

### DETAILED DESCRIPTION

The following description of the various embodiments is provided with reference to the accompanying drawings. The embodiments described with reference to the attached drawings are all exemplary and are intended to illustrate and interpret the present disclosure.

It should be understood that terms such as “top”, “bottom”, “upper”, “lower”, “front”, “rear”, “left”, “right”, “inside”, “outside”, “lateral”, “around”, “central”, “horizontal”, “vertical”, “longitudinal”, “axial”, “radial”, “uppermost”, “lowermost”, as well as derivative thereof should be construed to refer to the orientation as then described or as shown in the drawings under discussion. These relative terms are for convenience of description, do not require that the present disclosure be constructed or operated in a particular orientation, and shall not be construed as causing limitations to the present disclosure.

In conventional technology, encapsulation technology of organic light-emitting diode (OLED) devices usually includes glass plate encapsulation technology and thin film encapsulation (TFE) technology. Because the TFE technology does not need a rigid glass plate, the OLED devices may be bendable and foldable. Therefore, the TFE technology becomes a mainstream encapsulation trend currently. However, the TFE technology may only passively block moisture and oxygen, that is, the TFE technology may only block moisture and oxygen after an encapsulation layer is formed. Moisture and oxygen, which invade during process of manufacturing an encapsulation layer or invade from defects (gaps) of the encapsulation layer, cannot be blocked, thereby affecting long-term isolation capacity of the encapsulation layer. As a result, the present disclosure provides an improved encapsulation thin film to enhance the encapsulation thin film's ability to block moisture and oxygen.

One embodiment of the present disclosure provides an encapsulation thin film including at least one non-organic layer and at least one organic layer which are alternately stacked. The at least one organic layer includes an organic matrix and moisture absorbing material distributed in the organic matrix.

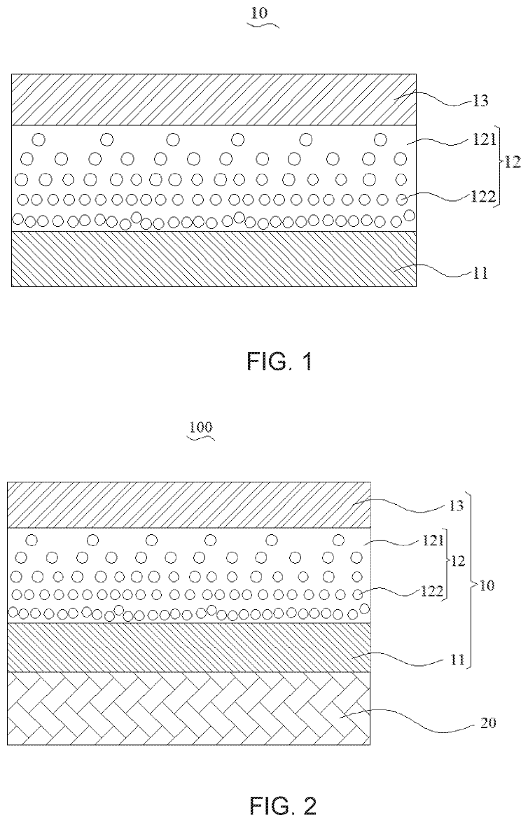

Specifically, referring to FIG. 1, FIG. 1 is a schematic structural view of an encapsulation thin film 10 according to an embodiment of the present disclosure. In the present embodiment, the encapsulation thin film 10 includes three films: a first non-organic layer 11, an organic layer 12, and a second non-organic layer 13 which are alternately stacked. The organic layer 12 includes an organic matrix 121 and moisture absorbing material 122 distributed in the organic matrix 121. Because properties of two non-organic layers are different, the organic layer 12 needs to be disposed therebetween to stabilize an organic light-emitting device.

Furthermore, the first non-organic layer 11 and the second non-organic layer 13 are insulating. Material of the first non-organic layer 11 and the second non-organic layer 13 may be SiOx, SiNx, or SiONx. The first non-organic layer 11 and the second non-organic layer 13 are formed by a spray coating process. Material of the first non-organic layer 11 and the second non-organic layer 13 may be the same or different. In the present embodiment, material of the first non-organic layer 11 and the second non-organic layer 13 are the same. Because the first non-organic layer 11 and the second non-organic layer 13 have good chemical stability and will not react with moisture and oxygen, the first non-organic layer 11 and the second non-organic layer 13 have great ability to block moisture and oxygen.

The organic layer 12 has strong stress characteristics and is used to alleviate diffusion of moisture and oxygen. The organic layer 12 includes the organic matrix 121 and the moisture absorbing material 122 distributed in the organic matrix 121.

The main component of the organic matrix 121 is a liquid organic solvent with polymethyl methacrylate, and other components of the organic matrix 121 may be epoxy resin and acrylate. The organic layer 12 is formed by spray coating an organic solvent with the moisture absorbing material 122 in a nitrogen environment.

Specifically, material of the moisture absorbing material 122 may be one or more of calcium oxide, magnesium sulfate, calcium sulfate, aluminum oxide, and barium oxide. In the present embodiment, preferred material of the moisture absorbing material 122 is calcium oxide. The calcium oxide is a white powder, which is very sensitive to humidity and is prone to absorb moisture. Therefore, moisture and oxygen, which invade during process of manufacturing an encapsulation layer or invade from defects (gaps) of the encapsulation layer, can be absorbed by the calcium oxide, thereby effectively reducing risk of failure, which is caused by erosion of moisture, of the OLED device. Further, after moisture is absorbed by the calcium oxide, oxygen dissolved in the moisture is unable to move, that is, transfer rate of oxygen is reduced so that oxygen can be further blocked. Moreover, magnesium sulfate, calcium sulfate, aluminum oxide, and cerium oxide are also commonly used chemical drying reagents, colors of them are white, and colors, sizes, and material properties of them after absorbing moisture will not seriously affect an encapsulation structure. In other embodiments, many chemical drying reagents may be used at the same time. Chemical drying reagents with slightly different hygroscopic properties complement each other, which improves effect of moisture absorption.

Further, the moisture absorbing material 122 are distributed in the organic matrix 121 in particle form. Particle sizes of the moisture absorbing material 122 are at the nanoscale level, that is, particle sizes of the calcium sulfate are at the nanoscale level and range from a few nanometers to a few hundred nanometers. Specifically, in the present embodiment, the particle sizes of the calcium sulfate range from 2 nm to 600 nm. In one embodiment, the particle sizes of the calcium sulfate may be 2 nm, 50 nm, 110 nm, 120 nm, 130 nm, 400 nm, or 600 nm. Further, a ratio of the particle sizes of the moisture absorbing material 122 to a thickness of the organic layer 12 ranges from 1/10000 to 1/100, thereby ensuring that properties change of the moisture absorbing material 122 caused by absorbing moisture will not affect the entire encapsulation thin film 110. In one embodiment, the ratio of the particle sizes of the moisture absorbing material 122 to the thickness of the organic layer 12 may be 1/1000, 1/5000, 1/1000, or 1/100. A thickness of the encapsulation thin film 110 may be decided by a display panel, a display device, or an OLED device to which the encapsulation thin film 110 is applied.

Specifically, referring to FIG. 1, in the present embodiment, a concentration of the moisture absorbing material 122 gradually increases along a direction from the second non-organic layer 13 toward the first non-organic layer 11. Therefore, flexibility of the entire encapsulation thin film 10 is improved. The moisture absorbing material 122 has the highest concentration at a side of the encapsulation thin film 10 near an organic light-emitting device. In other embodiments, the moisture absorbing material 122 may be distributed in the organic matrix 121 in a disorderly manner without concentration gradient, which may also have moisture absorbing effect. However, flexibility of the encapsulation thin film 10 will be lower.

Furthermore, the particle sizes of the absorbing material 122 may change (gradient) along the direction from the second non-organic layer 13 toward the first non-organic layer 11. For example, the particles sizes of the moisture absorbing material 122 may be gradually increased or decreased in the direction from the second non-organic layer 13 toward the first non-organic layer 11. In one embodiment, a concentration and particle sizes of the moisture absorbing material 122 are gradually increased in a gradient at the same time, which can fully alleviate concentrated forces between the organic layer 12 and the first non-organic layer 11 and between the organic layer 12 and the second non-organic layer 13. Therefore, flexibility of the entire encapsulation thin film 100 can be effectively improved.

In the above encapsulation thin films 10, the moisture absorbing material is added to the organic layer. The organic layer and the non-organic layer are alternately stacked. The moisture absorbing material is distributed in the organic matrix, thereby effectively absorbing moisture which invades during encapsulation process of manufacturing an OLED device or invades from defects of the encapsulation thin film 10, and transfer rate of oxygen is reduced as well. Moisture and oxygen can be effectively isolated from the OLED device, thereby effectively reducing risk of failure, which is caused by erosion of moisture, of the OLED device.

Referring to FIG. 2, FIG. 2 is a schematic structural view of an organic light-emitting display panel 100 according to an embodiment of the present disclosure. The organic light-emitting display panel 100 includes an organic light-emitting 20 and any of the above encapsulation thin films 10. The encapsulation thin film 10 covers a surface of the organic light-emitting device 20 and isolates the organic light-emitting device 20 from moisture and oxygen.

The organic light-emitting device 20 of the organic light-emitting panel is an OLED device including an anode, a hole transport layer, an organic luminescent layer, an electron transport layer, and a cathode. An entire structure of the organic light-emitting device 20 is similar to a sandwiched structure. Material of the anode is transparent. The anode injects holes when current flows through the anode. Material of the hole transport layer is an organic material, and the hole transport layer is used to transport the holes injected from the anode. Material of the organic luminescent layer is an organic material, and luminescence process occurs on the luminescent layer. Material of the electron transport layer is an organic material, and the electron transport layer is used to transport the electrons injected from the cathode. The cathode may be transparent or non-transparent. The cathode injects electrons when current flows through the cathode. When an external voltage is applied to the organic light-emitting display panel, holes injected by the anode and electrons injected by the cathode meet in the organic luminescent layer and recombine to form electron-hole pairs (excitons) which are in a bound state. The excitons radiatively decay and emerge energy as a photon of light.

Because the organic luminescent layer is very sensitive to humidity and oxygen, it is very important to prevent moisture and oxygen from invading and eroding the organic luminescent layer. The above encapsulation thin film 10 can be used to encapsulate and protect the organic light-emitting device. Specifically, the non-organic layer 11 of the encapsulation thin film 10 covers a surface of the above organic light-emitting device 20 during encapsulation process.

In the above organic light-emitting display panel, the encapsulation thin film 10 covers the organic light-emitting device 20. Therefore, the organic light-emitting layer and the cathode, which are prone to be eroded by moisture and oxygen, are well isolated and protected. As a result, the organic light-emitting display panel not only can provide a better user experience but also have long lifetime.

In other embodiments, a display device is further provided, including the above organic light-emitting display panel. The display device may be intelligent terminals such as a tablet, a desktop, a laptop, a mobile terminal, a television, or an intelligent interactive terminal.

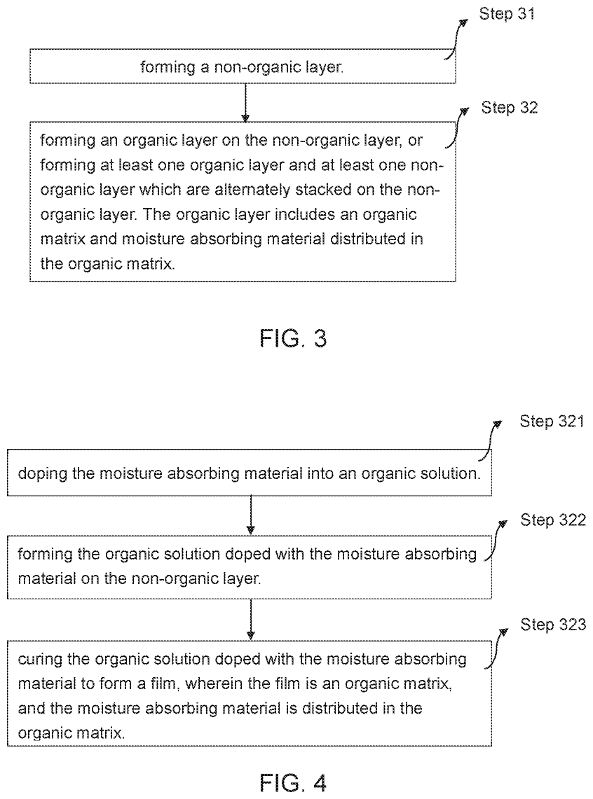

Referring to FIG. 3, FIG. 3 is a schematic flowchart showing a method of manufacturing an encapsulation thin film according to an embodiment of the present disclosure, including Step 31 to Step 33.

Step 31: forming a non-organic layer.

Material of the non-organic layer may be SiOx, SiNx, or SiONx. SiOx, SiNx, and SiONx have good chemical stability, which will not chemically react with moisture and oxygen and have exceptional ability to block moisture and oxygen. Therefore, they can be used in an OLED device as a covering film which is configured to block moisture and oxygen.

Step 32: forming an organic layer on the non-organic layer or forming at least one organic layer and at least one non-organic layer which are alternately stacked on the non-organic layer. The organic layer includes an organic matrix and moisture absorbing material distributed in the organic matrix.

After the Step 31 is finished, because properties of two non-organic layers are different, the organic layer needs to be disposed therebetween to stabilize an organic light-emitting device.

In the Step 32, the organic layer includes an organic matrix and moisture absorbing material distributed in the organic matrix. Specifically, a concentration of the moisture absorbing material gradually increases along a direction from the non-organic layer toward the organic layer. For example, when the encapsulation thin film includes two layers which are a non-organic layer an organic layer disposed on the non-organic layer. A concentration of the moisture absorbing material gradually increases along a direction from the non-organic layer toward the organic layer. As another example, the encapsulation thin film includes three layers which are a first non-organic layer, and an organic layer and a second non-organic layer which are sequentially disposed on the first non-organic layer. A concentration of the moisture absorbing material may gradually increasing along a direction from the second non-organic layer toward the first non-organic layer. Therefore, an outer layer, which is near a display substrate, of an OLED display panel has sufficient flexibility to be stretched.

Further, particle sizes of the moisture absorbing material may be changed in a gradient. For example, the particle sizes of the moisture absorbing material may gradually increase or gradually increase so that the encapsulation thin film can be used in different display panels.

Further, referring to FIG. 4, the step of forming an organic layer includes:

Step 321: doping the moisture absorbing material into an organic solution.

The main component of an organic solution is a liquid organic solvent with polymethyl methacrylate, and other components of the organic solvent may be epoxy resin and acrylate. The moisture absorbing material is doped into the organic solution. Material of the moisture absorbing material may be one or more of calcium oxide, magnesium sulfate, calcium sulfate, aluminum oxide, and barium oxide. In the present embodiment, material of the moisture absorbing material is calcium oxide. The calcium oxide is distributed in the organic matrix in particle form. Mass ratio of the organic solution to the calcium oxide ranges from 10000:1 to 100:5. Particle sizes of the calcium sulfate range from a few nanometers to a few hundred nanometers. The particle sizes of the calcium sulfate are only one ten thousandth to one hundredth of a thickness of the organic layer. The calcium sulfate will not seriously affect the encapsulation structure after it absorbs moisture.

Step 322: forming the organic solution doped with the moisture absorbing material on the non-organic layer.

In the step 322, the organic solution doped with the moisture absorbing material is coated on the non-organic layer by inkjet printing technology in a nitrogen environment. In an inert gas environment, properties of the moisture absorbing material such as calcium sulfate will not be affected. That is, moisture absorbing property of the calcium sulfate will not be affected.

Step 323: curing the organic solution doped with the moisture absorbing material to form a film, wherein the film is an organic matrix, and the moisture absorbing material is distributed in the organic matrix.

After the step 322 is finished, the organic solution needs to be converted from a liquid to a solid, which may be performed by thermal drying or natural drying. After the organic solution has been converted from a liquid to a solid, the organic solution is membranous, which is the above organic matrix, and the moisture absorbing material is distributed in the organic matrix.

The non-organic layer has a good ability to block moisture and oxygen but bad flexibility. A uniform film with great surface compactness is easy to be formed from the organic layer. By combining the non-organic layer and the organic layer, not only can moisture and oxygen be perfectly blocked, but extensibility and flexibility of an encapsulation thin film can be improved.

In the above method of manufacturing an encapsulation thin film, moisture absorbing material is added to an organic matrix. The moisture absorbing material is distributed in the organic matrix, thereby effectively absorbing moisture which invades during encapsulation process of manufacturing an organic light-emitting device or invades from defects of the encapsulation thin film. The organic light-emitting device can be isolated from moisture for a long time and can have extended lifetime.

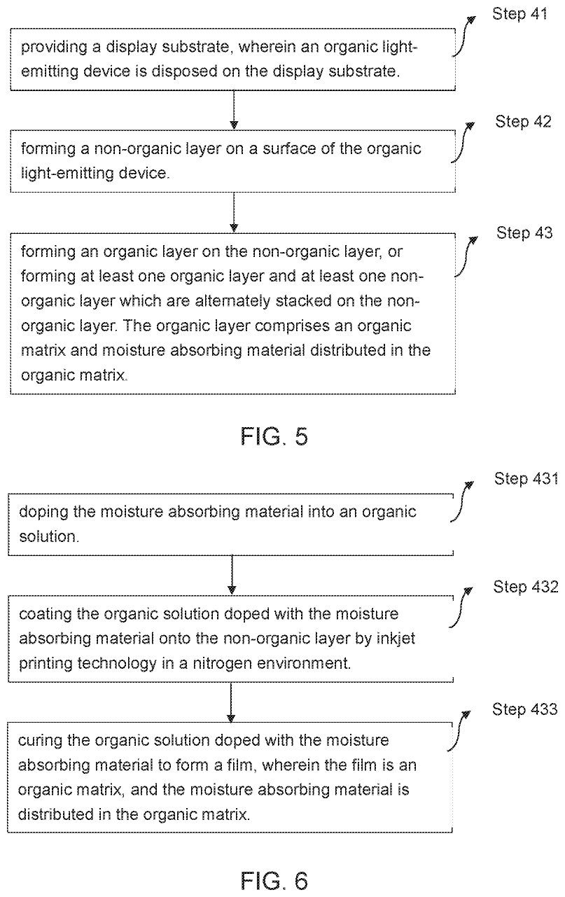

Referring to FIG. 5, FIG. 5 is a schematic flowchart showing a method of manufacturing an organic light-emitting display panel according to an embodiment of the present disclosure, including Step 41 to Step 44.

Step 41: providing a display substrate, wherein an organic light-emitting device is disposed on the display substrate.

The display substrate is a glass substrate, and the organic light-emitting device is the above OLED device.

Step 42: forming a non-organic layer on a surface of the organic light-emitting device.

Material of the non-organic layer may be SiOx, SiNx, or SiONx. SiOx, SiNx, and SiONx have good chemical stability, which will not chemically react with moisture and oxygen and have exceptional ability to block moisture and oxygen. Therefore, they can be used in the OLED device as a covering film which is configured to block moisture and oxygen.

Step 43: forming an organic layer on the non-organic layer, or forming at least one organic layer and at least one non-organic layer which are alternately stacked on the non-organic layer. The organic layer includes an organic matrix and moisture absorbing material distributed in the organic matrix.

The main component of the organic matrix is a liquid organic solvent with polymethyl methacrylate, and other components of the organic solvent may be epoxy resin and acrylate. The organic layer is formed by spray coating the organic solvent with moisture absorbing material in a nitrogen environment.

Specifically, material of the moisture absorbing material may be one or more of calcium oxide, magnesium sulfate, calcium sulfate, aluminum oxide, and barium oxide. In the present embodiment, material of the moisture absorbing material is calcium oxide. The calcium oxide is distributed in the organic matrix in particle form.

Furthermore, referring to FIG. 6, the step of forming the organic layer including an organic matrix and moisture absorbing material distributed in the organic matrix includes:

Step 431: doping the moisture absorbing material into an organic solution.

The main component of the organic solution is a liquid organic solvent with polymethyl methacrylate, and other components of the organic matrix may be epoxy resin and acrylate. The moisture absorbing material is doped into the organic solution. Material of the moisture absorbing material may be one or more of calcium oxide, magnesium sulfate, calcium sulfate, aluminum oxide, and barium oxide. In the present embodiment, material of the moisture absorbing material is calcium oxide. The calcium oxide is distributed in the organic matrix in particle form.

Step 432: coating the organic solution doped with the moisture absorbing material onto the non-organic layer by inkjet printing technology in a nitrogen environment.

In the step 432, the organic solution doped with the moisture absorbing material is coated onto the non-organic layer by inkjet printing technology in a nitrogen environment. In an inert gas environment, properties of the moisture absorbing material such as calcium sulfate will not be affected. That is, moisture absorbing property of the calcium sulfate will not be affected.

Step 433: curing the organic solution doped with the moisture absorbing material to form a film, wherein the film is the organic matrix, and the moisture absorbing material is distributed in the organic matrix.

After the step 432 is finished, the organic solution needs to be converted from a liquid to a solid, which may be performed by thermal drying or natural drying. After the organic solution has been converted from a liquid to a solid, the organic solution is membranous, which is the above organic matrix. The moisture absorbing material is distributed in the organic matrix.

In the above method of manufacturing an organic light-emitting display panel, the encapsulation thin film covers the organic light-emitting device of the display substrate. The encapsulation thin film includes at least one non-organic layer and at least one organic layer which are alternately stacked. The organic layer includes the organic matrix and the moisture absorbing material distributed in the organic matrix. That is, the moisture absorbing material is added to the organic matrix. Moisture which invades during encapsulation process of manufacturing an organic light-emitting device or invades from defects of the encapsulation thin film is absorbed by the moisture absorbing material. The organic light-emitting device can be isolated from moisture and oxygen for a long time. Therefore, user experience of the entire organic light-emitting display panel can be improved, and lifetime of the organic light-emitting display panel can be extended.

Although the invention has been shown and described with respect to one or more embodiments, equivalent variations and modifications can be realized by those skilled in the art upon reading and understanding the drawings of the present disclosure, and the present disclosure includes all such modifications and variations which are limited only by the appended claims. Regarding functions performed by the above components, terms used to describe such components are intended to correspond to any equivalent that performs the specified function of the components unless otherwise indicated, even if a structure of the equivalent is not identical to the disclosed structure of the present disclosure. Furthermore, although specific features of the specification have been disclosed with respect to only one of several embodiments, such features may be combined with one or more other features which is/are beneficial to realize the present disclosure. Moreover, it should be noted that “a plurality of” relates to two or more than two. For the steps mentioned in the present disclosure, the numerical suffix is only for the purpose of clearly expressing the embodiment, which does not completely represent the order of execution of the steps and should be set in consideration of the logical relationship.

The above description is only an embodiment which does not limit the patent scope of the present disclosure. Equivalent structure or equivalent process transformations based on the description of the present disclosure and the contents of the drawings, for example, the combination of technical features between the embodiments, or directly or indirectly applied in other related technical fields, are included within the scope of patent protection of the present disclosure.

What is claimed is:

1. An encapsulation thin film, comprising at least one non-organic layer and at least one organic layer which are alternately stacked;
wherein the at least one organic layer comprises an organic matrix and moisture absorbing material distributed in the organic matrix.

2. The encapsulation thin film of claim 1, wherein the moisture absorbing material comprises one or more of calcium oxide, magnesium sulfate, calcium sulfate, aluminum oxide, and barium oxide.

3. The encapsulation thin film of claim 1, wherein a concentration of the moisture absorbing material gradually increases along a direction from the at least one non-organic layer to the at least one organic layer.

4. The encapsulation thin film of claim 1, wherein the moisture absorbing material is distributed in the organic matrix in particle form, and a ratio of a diameter of a particle of the moisture absorbing material to a thickness of the at least one organic layer ranges from 1/10000 to 1/100.

5. The encapsulation thin film of claim 4, wherein the encapsulation thin film comprises a plurality of non-organic layers, and the diameter of the moisture absorbing material gradually increases along a direction from one non-organic layer to another non-organic layer.

6. An organic light-emitting display panel, comprising an organic light-emitting device;
wherein the organic light-emitting display panel further comprises an encapsulation thin film, and the encapsulation thin film comprises at least one non-organic layer and at least one organic layer which are alternately stacked; and
wherein the at least one organic layer comprises an organic matrix and moisture absorbing material distributed in the organic matrix, and one of the at least one non-organic layer of the encapsulation thin film covers a surface of the organic light-emitting device.

7. The organic light-emitting display panel of claim 6, wherein the moisture absorbing material comprises one or more of calcium oxide, magnesium sulfate, calcium sulfate, aluminum oxide, and barium oxide.

8. The organic light-emitting display panel of claim 6, wherein a concentration of the moisture absorbing material gradually increases along a direction from the at least one non-organic layer to the at least one organic layer.

9. The organic light-emitting display panel of claim 6, wherein the moisture absorbing material is distributed in the organic matrix in particle form, and a ratio of a diameter of a particle of the moisture absorbing material to a thickness of the at least one organic layer ranges from 1/10000 to 1/100.

10. The organic light-emitting display panel of claim 9, wherein the encapsulation thin film comprises a plurality of non-organic layers, and the diameter of the moisture absorbing material gradually increases along a direction from one non-organic layer to another non-organic layer.

11. A method of manufacturing an encapsulation thin film, comprising a plurality of steps of:
forming a non-organic layer; and
forming an organic layer on the non-organic layer; or
forming at least one non-organic layer and at least one organic layer which are alternately stacked on the non-organic layer;
wherein the organic layer comprises an organic matrix and moisture absorbing material distributed in the organic matrix.

12. The method of claim 11, wherein the step of forming an organic layer comprises a plurality of steps of:
doping the moisture absorbing material into an organic solution;
coating the organic solution doped with the moisture absorbing material onto the non-organic layer by inkjet printing technology in a nitrogen environment; and
curing the organic solution doped with the moisture absorbing material to form a film, wherein the film is an organic matrix, and the moisture absorbing material is distributed in the organic matrix.

13. The method of claim 11, wherein a concentration of the moisture absorbing material gradually increases along a direction from the non-organic layer to the organic layer.

14. The method of claim 11, wherein the moisture absorbing material is distributed in the organic matrix in particle form, and a ratio of a diameter of a particle of the moisture absorbing material to a thickness of the organic layer ranges from 1/10000 to 1/100.

15. The method of claim 14, wherein the encapsulation thin film comprises a plurality of non-organic layers, and the diameter of the moisture absorbing material gradually increases along a direction from one non-organic layer to another non-organic layer.
